(19) United States
(12) Patent Application Publication
(10) Pub. No.: US 2010/0265107 A1
(43) Pub. Date: Oct. 21, 2010

(54) SELF-DESCRIPTION OF AN ADAPTIVE INPUT DEVICE

(75) Inventors: Christopher Andrew Whitman, Denver, CO (US); Robert D. Young, Kirkland, WA (US); Christopher M. Dreher, Seattle, WA (US); Amar S. Vattakandy, Longmont, CO (US); Alain L. Michaud, Quebec (CA)

Correspondence Address: MICROSOFT CORPORATION, ONE MICROSOFT WAY, REDMOND, WA, 98052, US

(73) Assignee: MICROSOFT CORPORATION, Redmond, WA (US)

(21) Appl. No.: 12/425,235

(22) Filed: Apr. 16, 2009

(51) Int. Cl. H03M 11/00

(52) U.S. Cl. 341/23

(57) ABSTRACT

Methods and systems for self-description of an adaptive input device to a host computing device are herein provided. One exemplary adaptive keyboard includes one or more depressible keys and one or more touch regions, where each touch region is configured to positionally recognize a touch directed to that touch region. The adaptive keyboard may also include an adaptive imager to dynamically change a visual appearance of the one or more depressible keys and the one or more touch regions. Further, the adaptive keyboard may include firmware holding an adaptive descriptor to self-describe to the host computing device a renderable location of each of the one or more depressible keys and each of the one or more touch regions. The adaptive keyboard may further include a data link for communicating the adaptive descriptor to the host computing device.

### BACKGROUND

Computing systems can be used for work, play, and everything in between. To increase productivity and improve the user experience, attempts have been made to design input devices that offer the user an intuitive and powerful mechanism for issuing commands and/or inputting data.

### SUMMARY

Self-description of an adaptive input device to a host computing device is herein provided. One exemplary adaptive keyboard includes one or more depressible keys and one or more touch regions, where each touch region is configured to positionally recognize a touch directed to that touch region. The adaptive keyboard may also include an adaptive imager to dynamically change a visual appearance of the one or more depressible keys and the one or more touch regions in accordance with rendering information received from a host computing device. Further, the adaptive keyboard may include firmware holding an adaptive descriptor to self-describe to the host computing device a renderable location of each of the one or more depressible keys and each of the one or more touch regions. The adaptive descriptor may include, for each of the one or more depressible keys and each of the one or more touch regions, positioning data and size data. Positioning data may represent a point location of that depressible key or that touch region, and size data may represent a physical size of that depressible key or that touch region. The adaptive keyboard may further include a data link for communicating the adaptive descriptor to the host computing device.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1A illustrates a computing system including an adaptive input device in accordance with an embodiment of the present disclosure.

FIG. 1B illustrates dynamic updates to the visual appearance of the adaptive input device of FIG. 1A.

FIG. 2 is a sectional view of an adaptive keyboard.

FIG. 3 is a schematic view of an adaptive keyboard.

FIG. 4A and FIG. 4B illustrate descriptive characteristics of an adaptive keyboard stored in an adaptive descriptor of the adaptive keyboard.

FIG. 5 is a flowchart illustrating an exemplary method of self-describing a renderable location of each of a plurality of adaptive depressible keys to a host computing device.

### DETAILED DESCRIPTION

The present disclosure is related to an adaptive input device that can provide input to a variety of different computing systems. The adaptive input device may include one or more physical or virtual controls that a user can activate to effectuate a desired user input. The adaptive input device is capable of dynamically changing its visual appearance to facilitate user input. As a non-limiting example, the adaptive input device may dynamically change the appearance of one or more buttons. In some embodiments, the adaptive input device may additionally or alternatively dynamically change physical aspects of one or more regions, The visual appearance and/or physical aspects of the adaptive input device may be dynamically changed according to user preferences, application scenarios, system scenarios, etc., as described in more detail below.

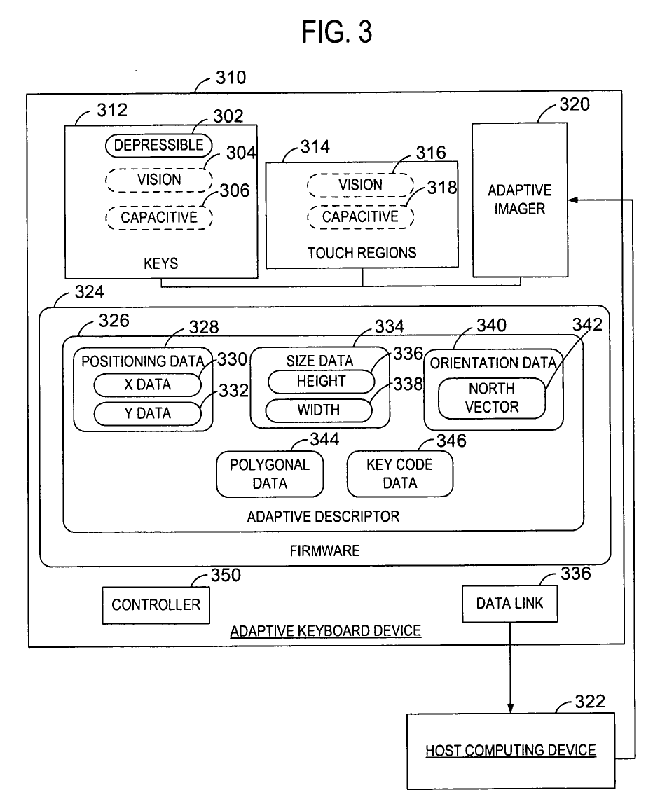

As explained in more detail below with reference to FIGS. 3-5, an adaptive input device may be configured to self-describe to a host computing device so that the host computing device can accurately display images at desired locations of the adaptive input device, such as at the buttons of the adaptive input device. In particular, an adaptive descriptor may be used to self-describe to the host computing device a renderable and/or touch-sensitive location of each of one or more depressible keys and/or other regions.

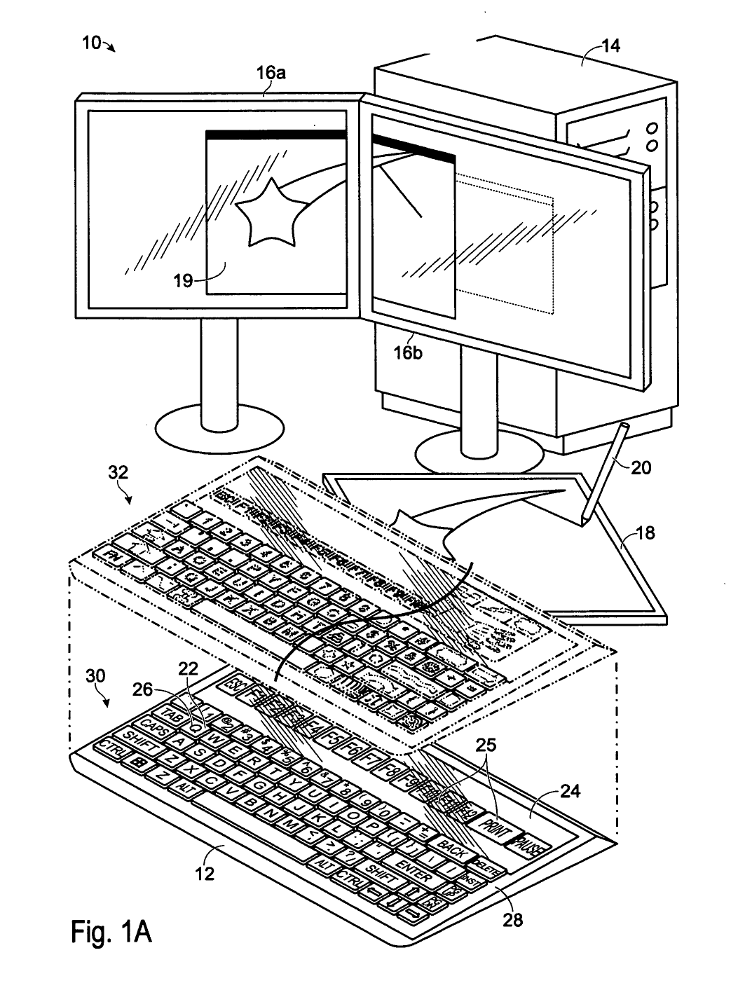

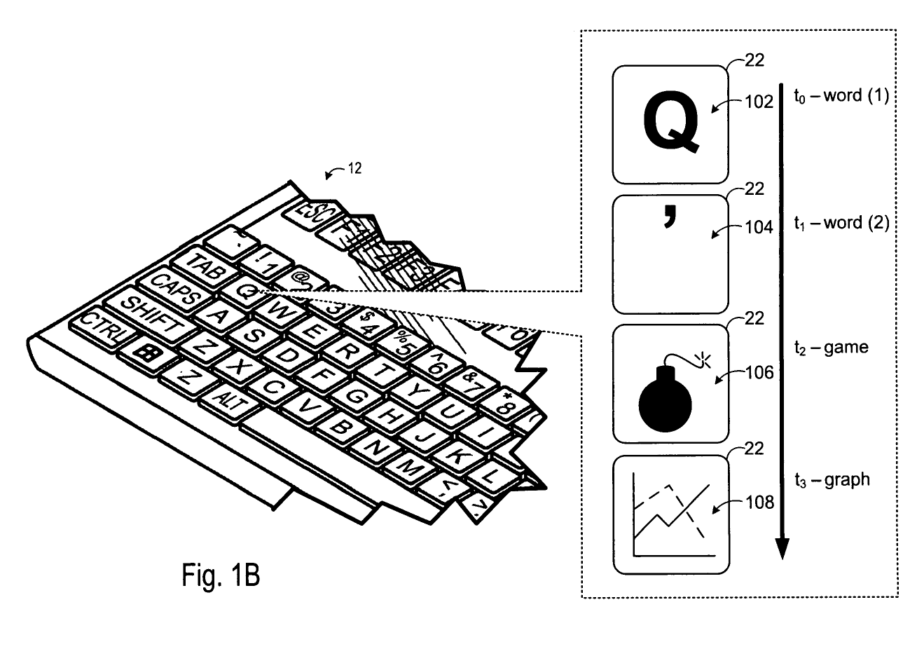

FIG. 1A shows a non-limiting example of a computing system 10 including an adaptive input device 12, such as an adaptive keyboard, with a dynamically changing appearance. The adaptive input device 12 is shown connected to a computing device 14. The computing device may be configured to process input received from adaptive input device 12. The computing device may also be configured to dynamically change an appearance of the adaptive input device 12.

Computing system 10 further includes monitor 16a and monitor 16b. While computing system 10 is shown including two monitors, it is to be understood that computing systems including fewer or more monitors are within the scope of this disclosure. The monitor(s) may be used to visually present visual information to a user.

Computing system 10 may further include a peripheral input device 18 receiving user input via a stylus 20, in this example. Computing device 14 may process an input received from the peripheral input device 18 and display a corresponding visual output 19 on the monitor(s). While a drawing tablet is shown as an exemplary peripheral input device, it is to be understood that the present disclosure is compatible with virtually any type of peripheral input device (e.g., keyboard, number pad, mouse, track pad, trackball, etc.).

In the illustrated embodiment, adaptive input device 12 includes a plurality of depressible keys (e.g., depressible buttons), such as depressible key 22, and touch regions, such as touch region 24 for displaying virtual controls 25. The adaptive input device may be configured to recognize when a key is pressed or otherwise activated. The adaptive input device 12 may also be configured to recognize touch input directed to a portion of touch region 24. In this way, the adaptive input device 12 may recognize user input.

Each of the depressible keys (e.g., depressible key 22) may have a dynamically changeable visual appearance. In particular, a key image 26 may be presented on a key, and such a key image may be adaptively updated. A key image may be changed to visually signal a changing functionality of the key, for example.

Similarly, the touch region 24 may have a dynamically changeable visual appearance. In particular, various types of touch images may be presented by the touch region, and such touch images may be adaptively updated. As an example, the touch region may be used to visually present one or more different touch images that serve as virtual controls (e.g., virtual buttons, virtual dials, virtual sliders, etc.), each of which may be activated responsive to a touch input directed to that touch image. The number, size, shape, color, and/or other aspects of the touch images can be changed to visually signal changing functionality of the virtual controls. It may be appreciated that one or more depressible keys may include touch regions, as discussed in more detail below.

The adaptive keyboard may also present a background image 28 in an area that is not occupied by key images or touch images. The visual appearance of the background image 28 also may be dynamically updated. The visual appearance of the background may be set to create a desired contrast with the key images and/or the touch images, to create a desired ambiance, to signal a mode of operation, or for virtually any other purpose.

By adjusting one or more of the key images, such as key image 26, the touch images, and/or the background image 28, the visual appearance of the adaptive input device 12 may be dynamically adjusted and customized. As nonlimiting examples, FIG. 1A shows adaptive input device 12 with a first visual appearance 30 in solid lines, and an example second visual appearance 32 of adaptive input device 12 in dashed lines.

The visual appearance of different regions of the adaptive input device 12 may be customized based on a large variety of parameters. As further elaborated with reference to FIG. 1B, these may include, but not be limited to: active applications, application context, system context, application state changes, system state changes, user settings, application settings, system settings, etc.

In one example, if a user selects a word processing application, the key images (e.g., key image 26) may be automatically updated to display a familiar QWERTY keyboard layout. Key images also may be automatically updated with icons, menu items, etc. from the selected application. For example, when using a word processing application, one or more key images may be used to present frequently used word processing operations such as “cut,” “paste,” “underline,” “bold,” etc. Furthermore, the touch region 24 may be automatically updated to display virtual controls tailored to controlling the word processing application. As an example, at t₀, FIG. 1B shows key 22 of adaptive input device 12 visually presenting a Q-image 102 of a QWERTY keyboard. At t₁, FIG. 1B shows the key 22 after it has dynamically changed to visually present an apostrophe-image 104 of a Dvorak keyboard in the same position that Q-image 102 was previously displayed.

In another example, if a user selects a gaming application, the depressible keys and/or touch region may be automatically updated to display frequently used gaming controls. For example, at t₂, FIG. 1B shows key 22 after it has dynamically changed to visually present a bomb-image 106.

As still another example, if a user selects a graphing application, the depressible keys and/or touch region may be automatically updated to display frequently used graphing controls. For example, at t₃, FIG. 1B shows key 22 after it has dynamically changed to visually present a line-plot-image 108.

As illustrated in FIG. 1B, the adaptive input device 12 dynamically changes to offer the user input options relevant to the task at hand. The entirety of the adaptive input device may be dynamically updated, and/or any subset of the adaptive input device may be dynamically updated. In other words, all of the depressible keys may be updated at the same time, each key may be updated independent of other depressible keys, or any configuration in between.

The user may, optionally, customize the visual appearance of the adaptive input device based on user preferences. For example, the user may adjust which key images and/or touch images are presented in different scenarios.

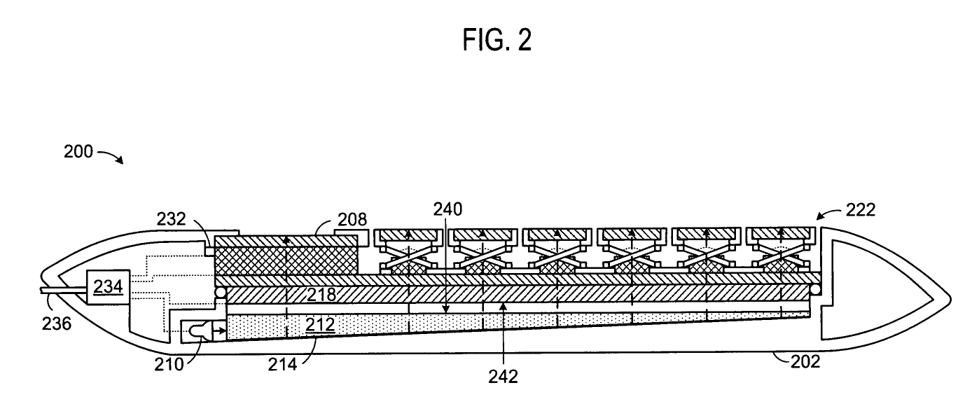

FIG. 2 is a sectional view of an example adaptive input device 200. The adaptive input device 200 may be a dynamic rear-projected adaptive keyboard in which images may be dynamically generated within the body 202 of adaptive input device 200 and selectively projected onto the plurality of depressible keys (e.g., depressible key 222) and/or touch regions (e.g., touch input display section 208).

A light source 210 may be disposed within body 202 of adaptive input device 200. A light delivery system 212 may be positioned optically between light source 210 and a liquid crystal display 218 to deliver light produced by light source 210 to liquid crystal display 218. In some embodiments, light delivery system 212 may include an optical waveguide in the form of an optical wedge with an exit surface 240. Light provided by light source 210 may be internally reflected within the optical waveguide. A reflective surface 214 may direct the light provided by light source 210, including the internally reflected light, through light exit surface 240 of the optical waveguide to a light input surface 242 of liquid crystal display 218.

The liquid crystal display 218 is configured to receive and dynamically modulate light produced by light source 210 to create a plurality of display images that are respectively projected onto the plurality of depressible keys, touch regions, or background areas (i.e., key images, touch images and/or background images).

The touch input display section 208 and/or the depressible keys (e.g., depressible key 222) may be configured to display images produced by liquid crystal display 218 and, optionally, to receive touch input from a user. The one or more display images may provide information to the user relating to control commands generated by touch input directed to touch input display section 208 and/or actuation of a depressible key (e.g., depressible key 222).

Touch input may be detected, for example, via capacitive or resistive methods, and conveyed to controller 234. It will be understood that, in other embodiments, other suitable touch-sensing mechanisms may be used, including vision-based mechanisms in which a camera receives an image of touch input display section 208 and/or images of the depressible keys via an optical waveguide. Such touch-sensing mechanisms may be applied to both touch regions and depressible keys, such that touch may be detected over one or more depressible keys in the absence of, or in addition to, mechanical actuation of the depressible keys.

The controller 234 may be configured to generate control commands based on the touch input signals received from touch input sensor 232 and/or key signals received via mechanical actuation of the one or more depressible keys. The control commands may be sent to a computing device via a data link 236 to control operation of the computing device. The data link 236 may be configured to provide wired and/or wireless communication with a computing device.

In order for a host computing device to render graphical display images on an adaptive keyboard, it is desirable for the host computing device to receive knowledge of exact locations and areas where graphical images can be displayed. For example, in order to display an image on a particular button, it is desirable that the host computing device know where that button is located. A host computing device may be connected to a variety of different adaptive devices, and thus may have to distinguish one adaptive device from another. Specifically, there may differences in the version, number of buttons, size of buttons, layout of buttons, orientation of buttons, number of touch regions, size of touch regions, layout of touch regions, orientation of touch regions, and/or other differences between different adaptive devices. Furthermore, third party software developers designing software for use with an adaptive device may be able to develop a better user experience with knowledge of physical characteristics of the adaptive keyboard. Furthermore, as the graphical images on keys and/or touch regions may be dynamically displayed, the computing functions associated with a particular key may change over time. Thus, it is desirable that the adaptive keyboard can dynamically describe itself to a host computing device.

While the above description provides the dynamic changing of a visual appearance of a region of an adaptive input device as an example, it is to be understood that an adaptive input device may additionally or alternatively be configured to dynamically change physical aspects of the adaptive input device. For example, a button of the adaptive input device may be configured to raise and lower. In such cases, the herein described adaptive descriptors may include information describing the physical aspects that can be changed for the various parts of the adaptive input device. In this way, a host computing system can learn what aspects of the adaptive input device may be changed.

Turning now to FIG. 3, a schematic view of an exemplary adaptive keyboard 310 is illustrated. As described in detail below, adaptive keyboard 310 is configured to self-describe characteristics of the adaptive keyboard 310 to an operating system or software application of a host computing device 322.

The exemplary adaptive keyboard 310 may include one or more keys 312. As indicated at 302, one or more of the keys 312 may be mechanically depressible. That is, a controller 350 of the adaptive keyboard may be configured to detect key signals from the mechanical actuation of one or more of the plurality of depressible keys. As indicated at 304, actuation and/or gesture detection of one or more of keys 312 may be vision-based. That is, components of the adaptive keyboard may have suitable optical properties such that the components are transparent to visible and infrared light wavelengths. Transparency in infrared wavelengths may allow an infrared vision-based touch detection system to be used to detect touches using a camera located within the adaptive keyboard, as described above with reference to FIG. 2. As indicated at 306, one or more of keys 312 may use capacitance to signal actuation and/or to detect gestures. That is, a change in capacitance may be detected upon touch of a key, for example by a user's finger acting as a conductor, and the location of the touch input accordingly detected. It is to be understood that a key may be configured to be actuated using a mechanism other than mechanical depression, vision-recognized touch, or capacitive-recognized touch without departing from the scope of this disclosure.

The adaptive keyboard 310 may also include one or more touch regions 314, which may include vision-based touch regions 316, capacitive touch regions 318, and/or other suitable touch regions respectively configured to positionally recognize a touch directed to that touch region, and to send key signals to host computing device 322 via data link 336 for processing at the host computing device 322.

As described with respect to FIG. 2, it is desirable to dynamically change an appearance of the adaptive keyboard 310. This may be accomplished, for example with the use of an adaptive imager 320 included in the adaptive keyboard 310. The adaptive imager 320 may dynamically change a visual appearance of the one or more depressible keys 312 and the one or more touch regions 314 in accordance with rendering information received from a host computing device 322. The adaptive imager 320 may include, for example, one or more of a light source, light delivery system, reflective surface, and liquid crystal display, such as those described with respect to FIG. 2.

The adaptive imager 320 may be configured to dynamically display one or more virtual input elements (e.g., touch image) on one or more depressible buttons 302 and one or more touch regions 314 in accordance with rendering information received from the host computing device 322, via data link 336. Further, the keys 312 and/or touch regions 314 may be configured to recognize a touch directed such virtual input elements.

In order to self-describe physical characteristics of the adaptive keyboard 310 to host computing device 322, in an efficient manner, the adaptive keyboard 310 may also include an adaptive descriptor 326. In some embodiments, the adaptive keyboard 310 may include firmware 324 for holding the adaptive descriptor 326. In other embodiments, the adaptive descriptor may be hardwired or saved on a built-in or removable storage medium.

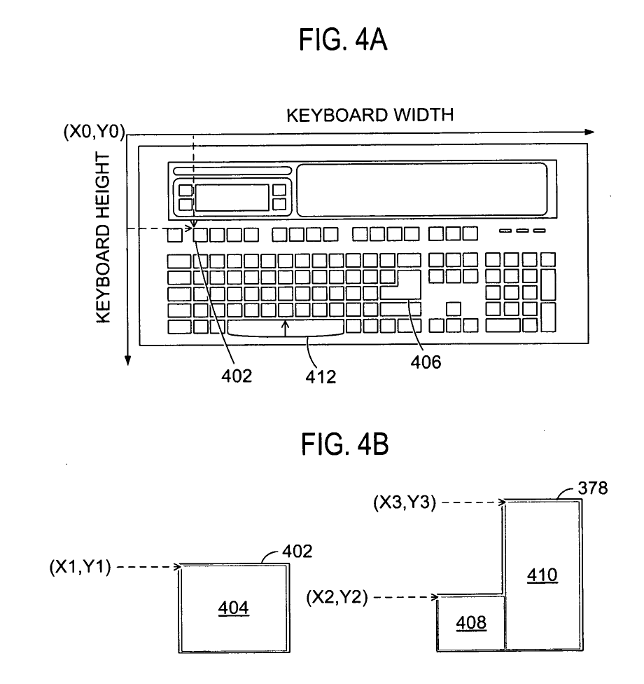

The adaptive descriptor 326 may communicate a displayable keyboard height and a displayable keyboard width, as illustrated in FIG. 4A, to the host computing device 322 to thereby define a keyboard region in which objects (e.g., graphical images) can be placed on the adaptive keyboard 310. The displayable keyboard height and displayable keyboard width may correspond to a liquid crystal display used to modulate display images, for example. Other characteristics of the adaptive keyboard 310 that may be communicated to the host computing device 322 via the adaptive descriptor 326 include, but are not limited to, a version (e.g., model, year), a number of independent regions, and a type of region (e.g., key, display only, touch only) of each of the one or more depressible keys 312 and/or touch regions 314 it contains.

Furthermore, the adaptive descriptor 326 may include resolution and physical dimensions of, for example, a liquid crystal display of the adaptive keyboard 310, as well as data formats (e.g., RGB 888, RGB565, GRAY8, etc.) the liquid crystal display, or the adaptive keyboard, may receive.

Further still, the adaptive descriptor 326 may self-describe to host computing device 322 a renderable location of each of the one or more depressible keys 312 and each of the one or more touch regions 314. In other words, the adaptive descriptor 326 is able to communicate, to the host computing device 322, information about the keys 312 and touch regions 314 that the host computing device 322 uses in order to provide instructions to the adaptive keyboard 310 to change the visual appearance of the adaptive keyboard 310. As well, the adaptive descriptor 326 is able to communicate, to the host computing device 322, information regarding a touch-sensitive area such that computing device 322 may appropriately recognize and process touch input.

Thus, positioning data 328 and size data 334 for describing a renderable and/or touch-sensitive location and size of each depressible key, and touch region, are included in the adaptive descriptor 326. Each depressible key and touch region may be divided into one or more blitable rectangles. As used herein, “blitable” refers to the ability to update the image at the region (e.g., rectangle). As such, a blitable region is a region that is capable of being visually updated. A blitable region may be updated independent of other blitable regions in some embodiments. The blitable rectangles may be represented, in data form, by positioning data 328 and size data 334 in the adaptive descriptor.

Referring now to FIG. 4A and FIG. 4B, for example, rectangular key 402 is substantially rectangular and, as such, may be divided into one blitable rectangle, such as blitable rectangle 404, for describing the renderable and/or touch-sensitive area of rectangular key 402. For non-rectangular shaped keys or touch regions (e.g., an L-shaped “enter” key, a curved “function” key), such as non-rectangular key 406, the renderable and/or touch-sensitive areas of the key may be described by multiple rectangles, such as blitable rectangle 408 and blitable rectangle 410.

Accordingly, one type of information that an adaptive descriptor (e.g., adaptive descriptor 326) may include for each of the one or more depressible keys and/or each of the one or more touch regions, is the positioning data (e.g., positioning data 328 of FIG. 3). Positioning data 328 may represent a point location, such as a top-left point location, of the one or more blitable rectangles of that depressible key or that touch region.

The positioning data 328 may be represented in the adaptive descriptor 326 by a plurality of positioning data pairs, such as liquid crystal display coordinates (e.g., X data 330 and Y data 332). Each data pair may thus collectively represent a blitable rectangle associated with a portion of that depressible key. In one example, a point location (e.g., upper left-hand corner) of substantially rectangular key 402 is described by blitable rectangle 404 with the positioning data (X1,Y1). In another example, non-rectangular key 406 includes two positioning data pairs (e.g., (X2,Y2) and (X3,Y3)) for describing point locations of blitable rectangle 408 and blitable rectangle 410, respectively. For non-rectangular key 406, one blitable rectangle that does not overlap with other keys, touch regions, and/or background space of the adaptive keyboard, may be insufficient for communicating the entire renderable area of a non-rectangular key. Thus, one or more additional positioning data pairs can be provided to respectively specify the top-left point location of one or more additional blitable rectangles. By including more than one blitable, rectangle, the renderable area of the key can be more accurately specified, without having the renderable location extend over an edge of the key being described. Thus, the plurality of such blitable rectangles cooperatively represent the renderable location of that depressible key. The blitable rectangles may be non-overlapping, such that all rectangles can be blit independently, or such that the rectangles can be blit together in a larger encompassing rectangle.

Another type of information that the adaptive descriptor 326 may include, for each of the one or more depressible keys and each of the one or more touch regions, is size data 334 representing a physical size of that depressible key or that touch region. Similarly to the positioning data pairs, the adaptive descriptor 326 may include a plurality of size data pairs. Size data pairs may include a height parameter 337, and a width parameter 338 associated with each renderable area of a depressible key or touch region. It may be desirable to include more than one size data pair, each size data pair representing a blitable rectangle, in order to more accurately describe the entire size of the blitable region of the key or touch region. Accordingly, each size data pair may collectively represent a blitable rectangle associated with a portion of that depressible key or that touch region. For example, rectangular key 402 may include one size data pair, whereas non-rectangular key 406 may include two size data pairs.

The adaptive descriptor 326 may also include, for each of the one or more depressible keys and/or each of the one or more touch regions, orientation data 340 representing a relative orientation of that depressible key. Orientation data 340 may include a north vector 342 for each of the depressible keys. As an example, “natural keyboards” include depressible keys oriented at an angle with respect to the vertical. A north vector for such a natural keyboard may indicate a 30 degree offset from the vertical, for one or more depressible keys. With respect to FIG. 4A, a north vector with a 0 degree offset from vertical is illustrated on space bar key 412. In this case, even though space bar key 412 is non-rectangular, the north vector does not have an offset from vertical.

Returning to FIG. 3, the adaptive descriptor 326 may also include, for each of the one or more depressible keys 312 and touch regions 314, polygonal data 344 representing a polygonal shape of that depressible key or touch region. It may be desirable to communicate the exact shape of a key. Polygonal data may include a number of points, or vertices in the polygon, and/or an array of points representing a display area for each key and/or touch region. The polygonal data may be a vector graphic, for example.

In order for actuation of the keys and/or touch regions to be properly interpreted at the host computing device 322, the adaptive descriptor 326 may include, for each of the one or more depressible keys and touch regions, key code data 346 including a key code for correlating that key or touch region to a desired key activation result.

The host computing device 322 may request key code data 346 at any time, and the adaptive keyboard 310 may send the key code data 346 via data link 336 responsive to the request.

Key code data 346 may be static, where the key code data 346 includes a plurality of key codes, each key code being associated with a key or touch region. In contrast, key code data 346 may be dynamic, where the key codes are associated with a particular computing function to be executed at the host computing device 322.

Referring to FIG. 1B, if the key code data 346 is static, a set of key codes representing keys and/or touch regions on the adaptive keyboard 310 may be sent to the host computing device 322. A first key code may be A1, which is assigned to key 22. Thus, when key 22 is actuated (e.g., touched, mechanically depressed, etc.), the host computing device may receive a key signal representing actuation of key 22, irrespective of the graphical image displayed on key 22. As described herein, graphical images may be dynamically displayed at the key 22 over time, where each graphical image is associated with a distinct computing function. For example, Q-image 102 is associated with the computing function “type a Q”, apostrophe-image 104 is associated with the computing function “type an apostrophe”, bomb-image 106 is associated with “drop a bomb”, and line-plot-image 108 is associated with computing function “draw a graph”. Accordingly, receipt of a key signal indicating actuation of key 22 may not include information regarding a desired computing function to be executed at the host computing device 322. Accordingly, the host computing device 322 may map the key signal representing actuation of key code 22 to an appropriate computing function based on the graphical image displayed at the key 22 of the adaptive keyboard 310 at the time the key signal was generated. In one example, the host computing device 322 may include a key code-graphical image look-up table and a graphical image-computing function look-up table for determining a computing function to execute responsive to receipt of a key signal representing actuation of key 22.

If the key code data 346 is dynamic, a key code for each key and/or touch region may change over time, for example, when the graphical images on one or more keys or touch regions changes. For example, key 22 may be assigned key code A1 when displaying a Q-image 102, key code A2 when displaying apostrophe-image 104, key code A3 when displaying a bomb-image 106, and key code A4 when displaying a line-plot-image 108. In one example, when host computing device 322 sends rendering information to adaptive imager 320, it may concurrently send a message to the adaptive keyboard 310 to assign new key codes to the keys and/or touch regions, based on the rendering information. Thus, upon actuation of, for example, key 22 of FIG. 1B, a key signal representing actuation of key code A1 may be sent to host computing device 322 if the Q-image 102 was displayed at time of actuation of key 22. Accordingly, key code A4 may be sent to host computing device if the line-plot-image 108 was displayed at time of actuation of key 22. That is, the key code associated with the graphical image displayed on the key 22 at the time of actuation of the key 22 is sent to the host computing device 322. Thus, upon receipt of the key signal representing a key code at the host computing device 322, the computing function associated with the key code can be looked up, for example, in a key code-computing function table, and the computing function can be executed.

In one example, a static key code data may include a first set of HID (Human Interface Device) usage identifiers. In another example, a dynamic key code data may include a second set of HID usage identifiers modified for the adaptive input device. In still another example, a set of key code data may be a set of non-HID usage identifiers.

Turning back to FIG. 3, the adaptive descriptor 326 may be formatted in an extensible markup language, as just one example. It is to be understood, however, that virtually any data structure may be used without departing from the spirit of this disclosure. It may be appreciated that the descriptors may be broken up into virtually any size for transmission, for example, 64 kilobyte chunks.

The adaptive keyboard 310 further includes a data link 336 for communicating the adaptive descriptor 326 to the host computing device 322. Data link 336 may include a USB (universal serial bus), IEEE 802.15.1 interface, or any other suitable wired or wireless data link.

It may be appreciated that an adaptive descriptor for each adaptive keyboard or adaptive input device may be calibrated to account for any keyboard-to-keyboard offsets that may occur, for example, during manufacturing.

It may be further appreciated that when an adaptive keyboard is connected to a host computing device, and the host computing device either does not include software requesting the adaptive descriptor as described herein, or includes software incapable of receiving and/or processing the adaptive descriptor described herein, an adaptive keyboard may be configured to send a standard set of key code data (e.g., Human Interface Device (HID) usage identifiers and/or descriptor identifiers) to allow conventional mechanical use of the adaptive keyboard.

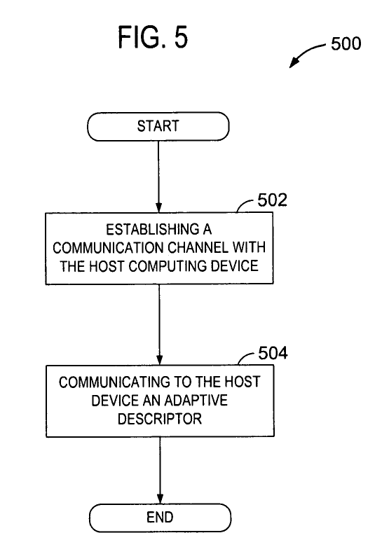

Referring now to FIG. 5, a flowchart illustrates an exemplary method 500 of self-describing a renderable location of each of a plurality of adaptive depressible keys to a host computing device. The method 500 may include, establishing a communication channel with the host computing device at 502. Such a communication channel may include, for example, a communication channel over a network and/or a USB connection.

The method 500 may further include communicating to the host computing device, via the communication channel, an adaptive descriptor at 504. As described with respect to FIG. 3, the adaptive descriptor may include, for each of the one or more depressible keys, positioning data representing a location of that depressible key, and size data representing a size of that depressible key. Once the adaptive descriptor is received at the host computing device, the host computing device may send rendering information to the adaptive input device, as described above.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. An adaptive keyboard, comprising:
one or more depressible keys;
one or more touch regions, each touch region configured to positionally recognize a touch directed to that touch region;
an adaptive imager to dynamically change a visual appearance of the one or more depressible keys and the one or more touch regions in accordance with rendering information received from a host computing device;
firmware holding an adaptive descriptor to self-describe to the host computing device a renderable location of each of the one or more depressible keys and each of the one or more touch regions, the adaptive descriptor including, for each of the one or more depressible keys and each of the one or more touch regions:
positioning data representing a point location of that depressible key or that touch region; and
size data representing a physical size of that depressible key or that touch region; and
a data link for communicating the adaptive descriptor to the host computing device.

2. The adaptive keyboard of claim 1, where the adaptive descriptor includes, for one or more of the depressible keys, a plurality of positioning data and size data pairs, each pair collectively representing a blitable rectangle associated with a portion of that depressible key, where a plurality of such blitable rectangles cooperatively represent the renderable location of that depressible key.

3. The adaptive keyboard of claim 1, where the adaptive descriptor includes, for each of the one or more depressible keys, orientation data representing a relative orientation of that depressible key.

4. The adaptive keyboard of claim 1, where the adaptive descriptor includes, for each of the one or more depressible keys, polygonal data representing a polygonal shape of that depressible key.

5. The adaptive keyboard of claim 1, where the adaptive descriptor is formatted in an extensible markup language.

6. An adaptive input device, comprising:
one or more depressible keys;
an adaptive imager to dynamically change a visual appearance of the one or more depressible keys in accordance with rendering information received from a host computing device; and
an adaptive descriptor to self-describe to the host computing device a renderable location of each of the one or more depressible keys.

7. The adaptive input device of claim 6, where the adaptive descriptor includes, for each of the one or more depressible keys, positioning data representing a point location of that depressible key.

8. The adaptive input device of claim 7, where the positioning data represents a top-left point location in display coordinates for that depressible key.

9. The adaptive input device of claim 6, where the adaptive descriptor includes, for each of the one or more depressible keys, size data representing a physical size of that depressible key.

10. The adaptive input device of claim 6, where the adaptive descriptor includes, for one or more of the depressible keys, a plurality of positioning data and size data pairs, each pair collectively representing a blitable rectangle associated with a portion of that depressible key, where a plurality of such blitable rectangles cooperatively represent the renderable location of that depressible key.

11. The adaptive input device of claim 6, where the adaptive descriptor includes, for each of the one or more depressible keys, orientation data representing a relative orientation of that depressible key.

12. The adaptive input device of claim 6, where the adaptive descriptor includes, for each of the one or more depressible keys, a key code for correlating that key to a desired key activation result.

13. The adaptive input device of claim 6, where the adaptive descriptor includes, for each of the one or more depressible keys, polygonal data representing a polygonal shape of that depressible key.

14. The adaptive input device of claim 6, further comprising one or more touch regions, where the adaptive imager is configured to dynamically display one or more virtual input elements on a touch region in accordance with rendering information received from a host computing device, and where that touch region is configured to recognize a touch directed to a virtual input element.

15. The adaptive input device of claim 14, where the adaptive descriptor includes, for each of the one or more touch regions, positioning data representing a point location of that touch region.

16. The adaptive input device of claim 15, where the positioning data represents a top-left point location in display coordinates for that touch region.

17. The adaptive input device of claim 14, where the adaptive descriptor includes, for each of the one or more touch regions, size data representing a physical size of that touch region.

18. The adaptive input device of claim 6, where the adaptive descriptor is formatted in an extensible markup language.

19. The adaptive input device of claim 6, further comprising a data link for communicating the adaptive descriptor to the host computing device.

20. An adaptive input device, comprising:
one or more touch regions, each touch region configured to positionally recognize a touch directed to that touch region;
an adaptive imager to dynamically change a visual appearance of the one or more touch regions in accordance with rendering information received from a host computing device;
firmware holding an adaptive descriptor to self-describe to the host computing device a renderable location of each of the one or more touch regions; and
a data link for communicating the adaptive descriptor to the host computing device.
